(19) United States
(12) Patent Application Publication
(10) Pub. No.: US 2017/0367216 A1
(43) Pub. Date: Dec. 21, 2017

(54) WATER COOLING DEVICE

(71) Applicant: ASIA VITAL COMPONENTS CO., LTD., New Taipei City (TW)

(72) Inventor: Ching-Hang Shen, New Taipei City (TW)

(21) Appl. No.: 15/183,795

(22) Filed: Jun. 16, 2016

(51) Int. Cl. H05K 7/20; F28D 15/00; F28F 19/02; F28F 3/02; F28D 21/00

(52) U.S. Cl. CPC H05K 7/20272; F28F 19/02; F28F 3/02; F28D 15/00; F28D 2021/0031; F28F 2230/00; F28F 2250/08

(57) ABSTRACT

The present invention relates to a water cooling device which comprises a liquid storing shell body having a liquid chamber and a pump having a stator and a rotor. The stator has a coil set disposed electrically on a circuit board. The circuit board and the coil set thereon are both disposed on at least one inner wall of the liquid chamber or integrally overmolded in the liquid storing shell body. The rotor and a propeller oppositely connected to the rotor are received in the liquid chamber and exposed in the cooling liquid. The propeller is provided with a plurality of blades made of metal. At least one magnetic pole region is magnetized on each of the blades opposite to the coil set. Therefore, a thinning effect can be achieved.

### BACKGROUND OF THE INVENTION

### Field of the Invention

The present invention relates to a water cooling device and in particular to a water cooling device which has a thinning effect.

### Description of Prior Art

As the operating capacity of the electronic device increases, the electronic components disposed therein will generate large amount of heat during operation. Heat sinks or cooling fins are generally required to be installed on the electronic components to increase the heat dissipation area and thus enhance heat dissipation efficiency. However, because the heat dissipation efficiencies of the heat sinks and the cooling fins are limited, a traditional water cooling device of the prior art technology is used to enhance the heat dissipation efficiency.

The traditional water cooling device can perform heat exchange between the heat generating device such as a processing unit or a graphics processing unit and a cooling liquid in the water cooling device. Then, the cooling liquid is circulated by a pump in the water cooling device. Also, the water cooling device is connected to a heat sink through plural pipes such that the cooling liquid is used to perform heat exchange and cyclic heat dissipation between the heat sink and the water cooling device. As a result, the heat generating device can quickly dissipate the heat.

In the above traditional prior art water cooling device, in order to protect the stator assembly of the pump from damage by contact with liquid, the stator assembly is disposed outside the water cooling device and the rotor assembly which guides the cooling liquid to circulate in the water cooling device is disposed in a chamber of the water cooling device. The stator assembly and the rotor assembly are magnetically excited to operate through the outer shell of the water cooling device. Due to the concern of the structural strength of the outer shell of the water cooling device, the outer shell has a specific thickness. Consequently, the gap caused by the thickness of the outer shell of the water cooling device between the rotor assembly and the stator assembly influences the operation efficiency of the pump, which causes the problems of poor efficiency of whole heat dissipation of the water cooling device and an excessive volume of the entire water cooling device.

### SUMMARY OF THE INVENTION

Thus, to effectively overcome the above problems, one objective of the present invention is to provide a water cooling device which can achieve a thinning effect.

Another objective of the present invention is to provide a water cooling device which can reduce the thickness gap between the stator and the corresponding rotor and decrease the entire volume thereof.

Yet another objective of the present invention is to provide a water cooling device which can reduce the flow speed to prevent eddies (or turbulence) by means of a first inclined surface of a water channel and a second inclined surface on an internal wall of a heat exchange chamber in which there is a step difference formed between the first and the second inclined surfaces. Also, the second inclined surface is adjacent to, connected to, and opposite to the first inclined surface

To achieve the above objectives, the present invention provides a water cooling device which comprises a liquid storing shell body and a pump. The liquid storing shell body has a liquid chamber, an inlet, and an outlet; the liquid chamber communicates with the inlet and the outlet to allow a cooling liquid to flow through the interior thereof. The pump is used to circulate the cooling liquid and comprises a stator and a rotor. The stator has a coil set disposed electrically on a circuit board. The circuit board and the coil set thereon are both disposed on at least one inner wall of the liquid chamber or integrally overmolded in the liquid storing shell body. The circuit board and the coil set are both isolated from the cooling liquid. The rotor and a propeller oppositely connected to the rotor are received in the liquid chamber and exposed in the cooling liquid. The propeller is provided with a plurality of blades made of metal. At least one magnetic pole region is magnetized on each of the blades opposite to the coil set. The magnetic pole region of the each of the blades is inductively excited by the coil set.

In one embodiment, an upper edge or a lower edge of the each of the blades is axially magnetized to form the magnetic pole region. A protective film surrounding the circuit board and the coil set is disposed on an internal top wall or an internal bottom wall of the liquid chamber and corresponds to the magnetic pole regions of the blades.

In one embodiment, a front edge of the each of the blades is radially magnetized to form the magnetic pole region. A protective film surrounding the circuit board and the coil set is disposed on an internal side wall of the liquid chamber and corresponds to the magnetic pole regions of the blades.

In one embodiment, the circuit board and the coil set are integrally overmolded inside a top portion or a bottom portion of the liquid storing shell body and correspond to the magnetic pole regions of the blades. The circuit board and the stator are disposed outside the liquid chamber. The liquid storing shell body isolates the cooling liquid from the stator and the circuit board.

In one embodiment, the circuit board and the coil set are integrally overmolded inside a side portion of the liquid storing shell body and correspond to the magnetic pole regions on the front edges of the blades. The circuit board and the stator are disposed outside the liquid chamber. The liquid storing shell body isolates the cooling liquid from the stator and the circuit board.

In one embodiment, the rotor has a shaft. One end of the shaft is connected to the propeller and the other end of the shaft is axially disposed on an internal wall of the liquid chamber. The inlet and the outlet are individually disposed on two sides of the liquid storing shell body.

In one embodiment, the water cooling device further comprises a heat exchange component oppositely connected to the liquid storing shell body. The heat exchange component has a heat contact surface and a heat exchange surface which contacts the cooling liquid in the liquid chamber.

In one embodiment, the water cooling device further comprises a heat exchange component oppositely connected to the liquid storing shell body. The liquid storing shell body further comprises a separation part, at least one throughhole, and a water channel. The separation part is formed at the middle of the liquid storing shell body. The separation part, the liquid storing shell body, and the heat exchange component together define the liquid chamber and a heat exchange chamber communicating with the outlet. The throughhole is formed on the separation part and communicates with the inlet and the liquid chamber which is disposed above the heat exchange chamber. The water channel is disposed between the liquid chamber and an internal side wall of the liquid chamber and penetrates through the separation part to communicate with the heat exchange chamber.

In one embodiment, the water channel has a first inclined surface extending from the bottom of the water channel in the liquid chamber to penetrate through the separation part and slope downward. A second inclined surface is disposed on an internal wall of the heat exchange chamber opposite to the water channel. The second inclined surface is adjacent to, connected to, and opposite to the first inclined surface.

### BRIEF DESCRIPTION OF DRAWING

FIG. 1 is a perspective exploded view of the water cooling device according to the first embodiment of the present invention;

FIG. 2 is a perspective assembled view of the water cooling device according to the first embodiment of the present invention;

FIG. 2A is a cross-sectional view of the water cooling device according to the first embodiment of the present invention;

FIG. 2B is a partial enlarged cross-sectional view of the water cooling device according to the first embodiment of the present invention;

FIG. 3A is an embodiment of the cross-sectional view of the water cooling device according to the first embodiment of the present invention;

FIG. 3B is another embodiment of the cross-sectional view of the water cooling device according to the first embodiment of the present invention;

FIG. 4A is yet another embodiment of the cross-sectional view of the water cooling device according to the first embodiment of the present invention;

FIG. 4B is still yet another embodiment of the cross-sectional view of the water cooling device according to the first embodiment of the present invention;

FIG. 4C is another embodiment of the cross-sectional view of the water cooling device according to the first embodiment of the present invention;

FIG. 5A is a perspective exploded view of the water cooling device according to the second embodiment of the present invention;

FIG. 5B is a cross-sectional view of the water cooling device according to the second embodiment of the present invention;

FIG. 6 is an applicable embodiment of the water cooling device according to the second embodiment of the present invention;

FIG. 7 is a perspective exploded view of the water cooling device according to the third embodiment of the present invention;

FIG. 8A is a perspective assembled view of the water cooling device according to the third embodiment of the present invention;

FIG. 8B is a cross-sectional view of the water cooling device according to the third embodiment of the present invention; and

FIG. 8C is another embodiment of the cross-sectional view of the water cooling device according to the third embodiment of the present invention.

### DETAILED DESCRIPTION OF THE INVENTION

The above objectives, structural and functional characteristics of the present invention will be described according to the preferred embodiments in the accompanying drawings.

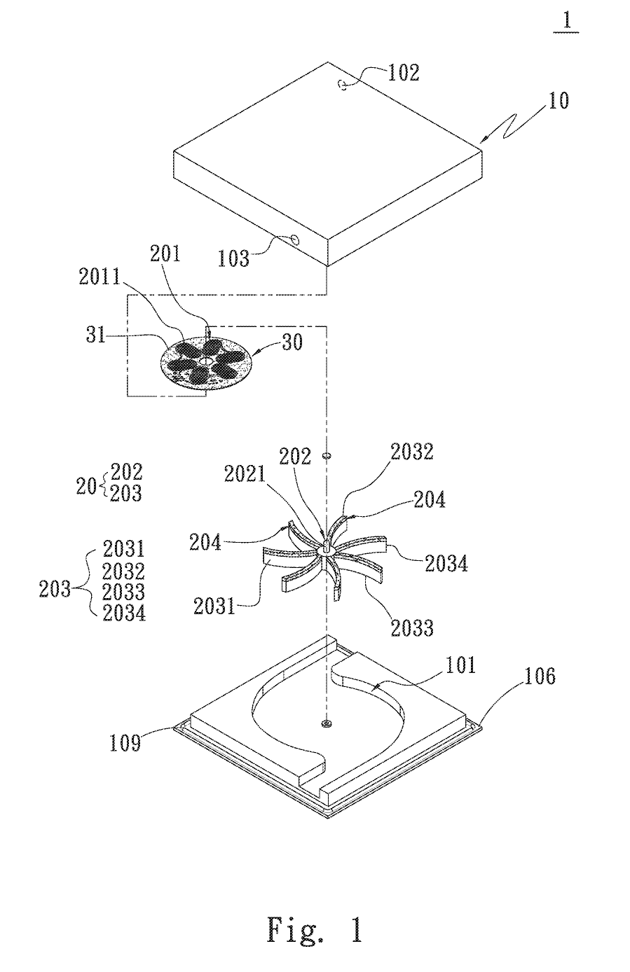

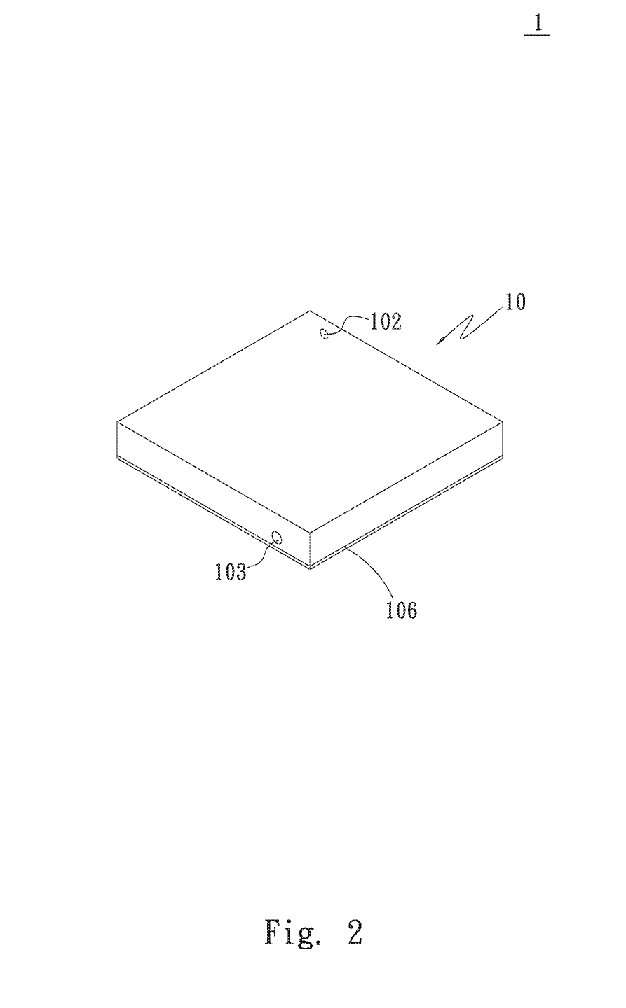

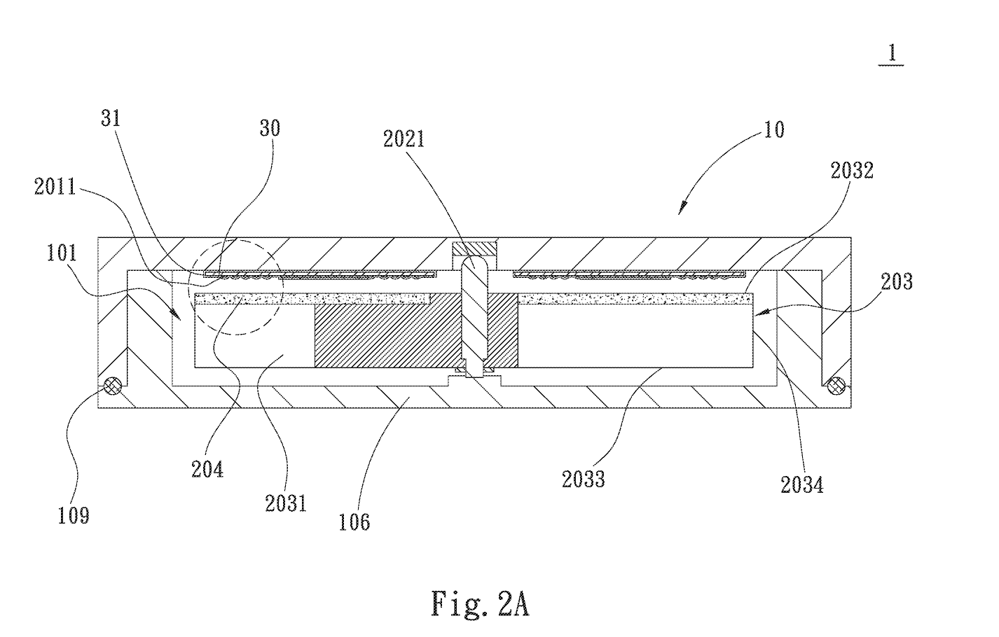

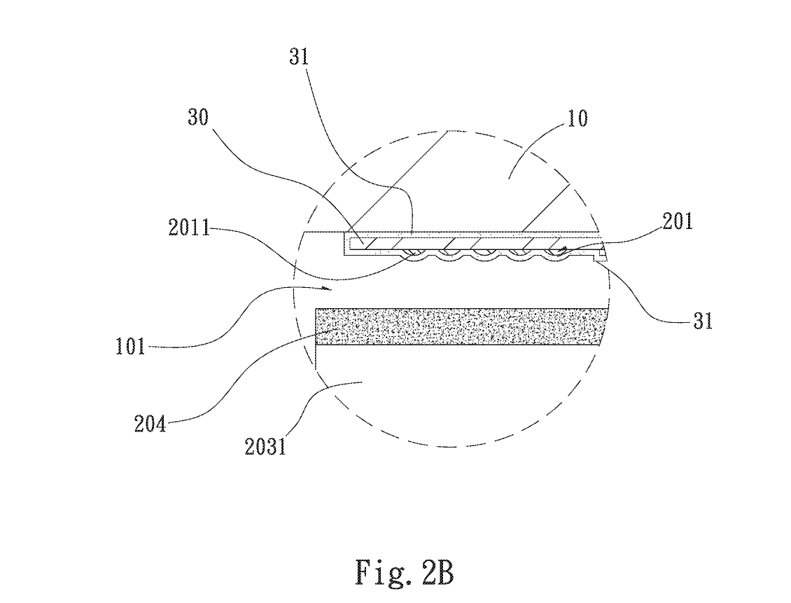

The present invention provides a water cooling device, referring to FIGS. 1, 2, and 2A which show the perspective exploded view, the perspective assembled view, and the cross-sectional view of the water cooling device according to the first embodiment of the present invention, respectively. The water cooling device 1 comprises a liquid storing shell body 10 and a pump 20. The liquid storing shell body 10 is made of plastic and has a liquid chamber 101, an inlet 102, an outlet 103, and a bottom cover 106. The bottom side of the liquid storing shell body 10 is directly connected to an end surface of the bottom cover 106 to seal the liquid chamber 101. The liquid chamber 101 communicates with the inlet 102 and the outlet 103 to allow a cooling liquid to flow through the interior thereof. The inlet 102 and the outlet 103 are individually disposed on two sides of the liquid storing shell body 10. A washer 109 is disposed between the bottom cover 106 and the liquid storing shell body 10. The washer 109 is used to increase the sealing strength between the liquid storing shell body 10 and the bottom cover 106 to prevent the cooling liquid from seeping out of the liquid chamber 101. The above-mentioned bottom cover 106 is part of the liquid chamber 101. The combination of the bottom cover 106 and the liquid chamber 101 is made by embedment, used for explanation, and is not limited to this. In a specific embodiment, the above-mentioned combination can be made by adhesion or by screwing.

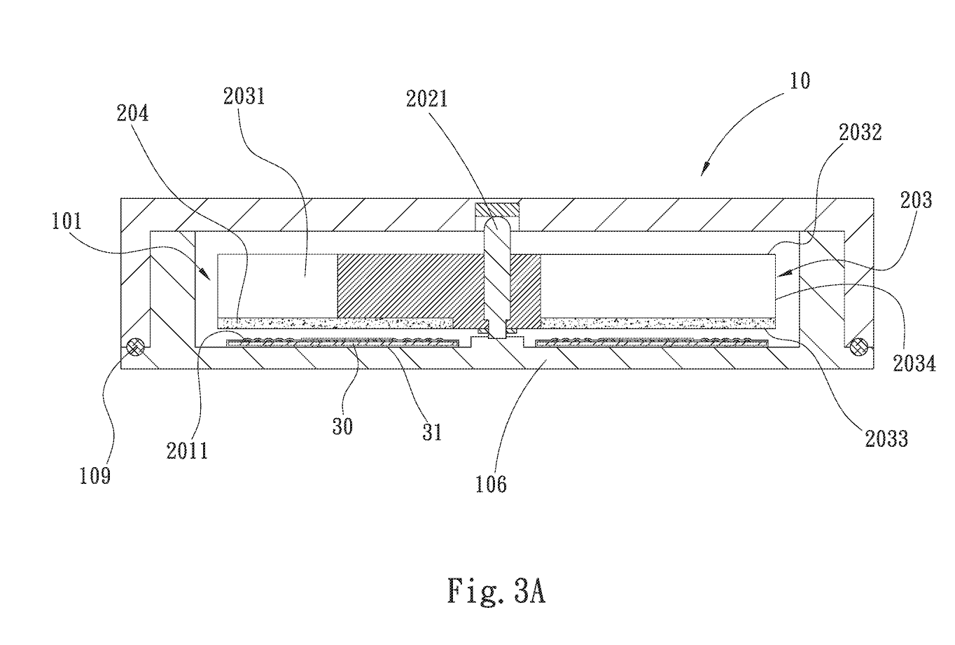

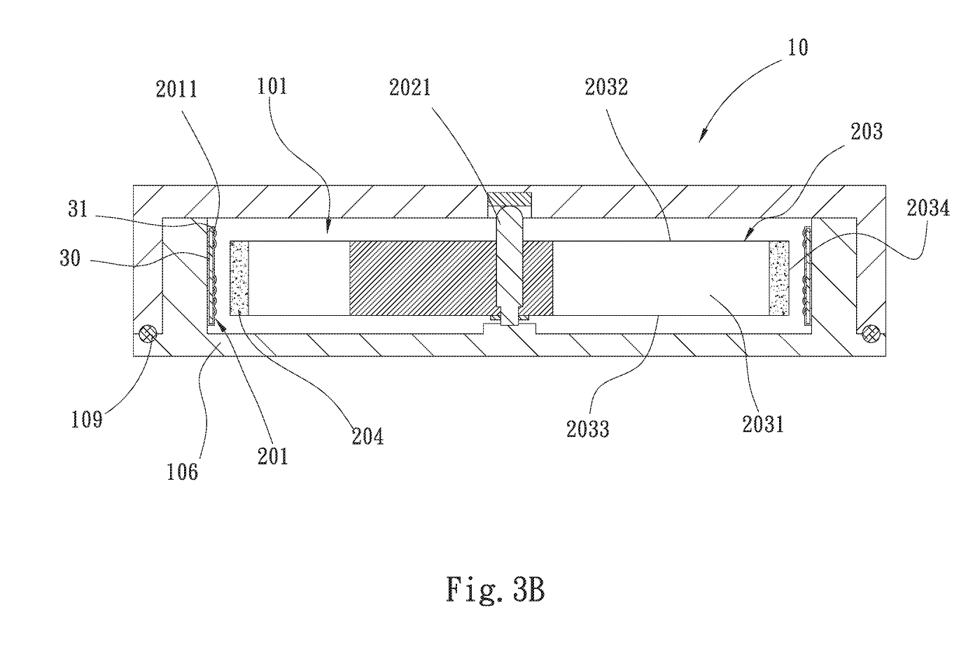

The pump 20 is used to circulate the cooling liquid and comprises a stator 201, a rotor 202, and a propeller 203. The stator 201 has a coil set 2011 which is formed on a circuit board 30 by disposition, layout, etching, or printing in the current embodiment. Also, the coil set 2011 is disposed electrically on one side of the circuit board 30. In a specific embodiment, the coil set 2011 can be formed on one side of the circuit board 30 by stacking or by layout. In the current embodiment, the circuit board 30 and the coil set 2011 thereon are both disposed on at least one inner wall of the liquid chamber 101; the circuit board 30 and the coil set 2011 are both isolated from the cooling liquid. Besides, a protective film 31 (or a coating) surrounds the circuit board 30 and the coil set 2011; the protective film 31 (or the coating) is used to isolate the cooling liquid from the stator 201 and the circuit board 30. In the current embodiment shown in FIGS. 2A and 2B, the circuit board 30 and the coil set 2011 both surrounded by the protective film 31 are adhered to each other and are disposed on an internal top wall of the liquid chamber 101. In an alternative embodiment shown in FIG. 3A, the circuit board 30 and the coil set 2011 both surrounded by the protective film 31 are adhered to each other and are disposed an internal bottom wall of the liquid chamber 101. In an alternative embodiment shown in FIG. 3B, the circuit board 30 and the coil set 2011 both surrounded by the protective film 31 are adhered to each other and are disposed an internal side wall of the liquid chamber 101. The above-mentioned circuit board 30 is a flexible printed circuit board (FPCB) or a printed circuit board (PCB), one end of which is electrically connected to a connecting wire set (not shown). One end of the connecting wire set is electrically connected to the circuit board 30 and the other end of the connecting wire set extends from the liquid chamber 101 and penetrates through the liquid storing shell body 10 to the outside thereof such that the other end of the connecting wire set is connected to a mother board (or a power supply) correspondingly. The place where the other end of the connecting wire set penetrates through the liquid storing shell body 10 from the liquid chamber 101 is sealed to prevent the cooling liquid from seeping out of the liquid chamber 101. In an alternative embodiment, one end of the connecting wire set is electrically connected to the circuit board 30 and the other part (i.e., the portion between the one end and the other end of the connecting wire set) are integrally overmolded in the liquid storing shell body 10 and the other end of the connecting wire set is exposed outside the liquid storing shell body 10 to be correspondingly connected to the mother board (or the power supply, not shown). Moreover, the connecting wire set in the current embodiment includes power wires and control signal wires. The power wires are used to provide power for the electronic components on the circuit board 30 and the pump 20; the control signal wires are used to control the rotating speed of the pump (or to control the switching on/off of the pump at the same time).

In addition, the rotor 202 is connected to the propeller 203 both of which are received in the liquid chamber 101 and exposed in the cooling liquid such that the rotor 202 corresponds to the stator 201 and the rotor 202 is driven to rotate the propeller 203. Then, the propeller 203 stirs the cooling liquid in the liquid chamber 101. The cooling liquid flowing in through the inlet 102 is moved by the propeller 203 to flow out through the corresponding outlet 103. The rotor 202 has a shaft 2021. One end of the shaft 2021 is connected to the propeller 203 and the other end of the shaft 2021 is axially disposed on the internal wall of the liquid chamber 101. The propeller 203 is provided with a plurality of blades 2031 made of metal; at least one magnetic pole region 204 is magnetized on each of the blades 2031 opposite to the coil set 2011. That is, in the current embodiment, an upper edge 2032 of each of the blades 2031 is axially magnetized to form the magnetic pole region 204. The upper edges 2032 of each two adjacent blades 2031 have different magnetic pole regions 204 (a north pole or a south pole). The magnetic pole region 204 on the upper edge 2032 of each of the blades 2031 is inductively excited by the opposite coil set 2011 on the internal top wall of the liquid chamber 101. Thus, the rotor 202 is driven to rotate.

In an alternative embodiment shown in FIG. 3A, a lower edge 2033 of the each of the blades 2031 is axially magnetized to form the magnetic pole region 204 and the lower edges 2033 of each two adjacent blades 2031 have different magnetic pole regions 204 (a north pole or a south pole). The magnetic pole region 204 on the lower edge 2033 of each of the blades 2031 is inductively excited by the opposite coil set 2011 on the internal bottom wall of the liquid chamber 101. In an alternative embodiment shown in FIG. 3B, a front edge 2034 of the each of the blades 2031 is radially magnetized to form the magnetic pole region 204 and the front edges 2034 of each two adjacent blades 2031 have different magnetic pole regions 204 (a north pole or a south pole). The magnetic pole region 204 on the front edge 2034 of each of the blades 2031 is inductively excited by the opposite coil set 2011 on the internal side wall of the liquid chamber 101.

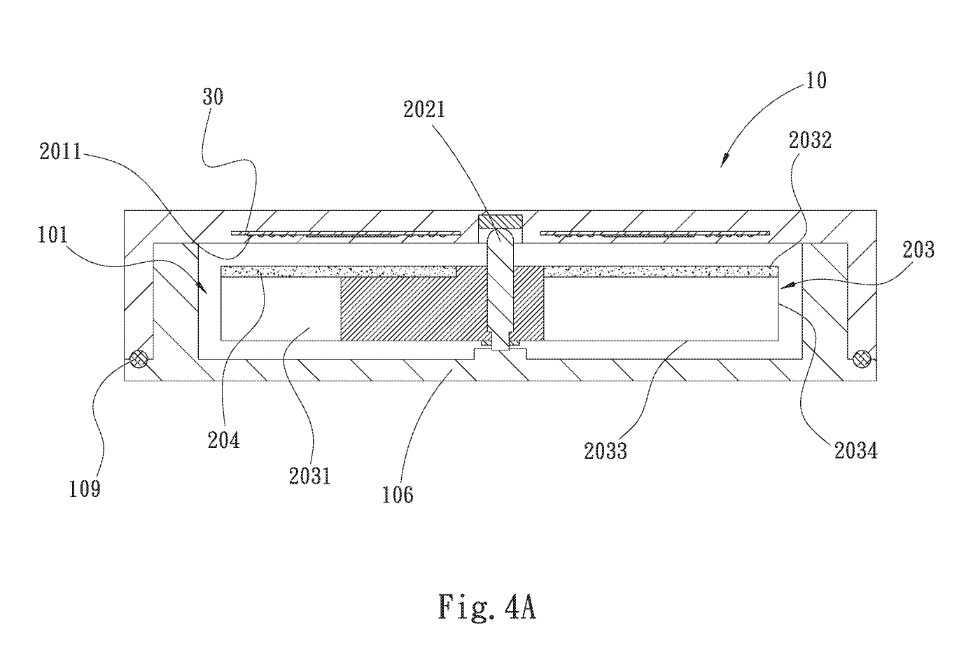

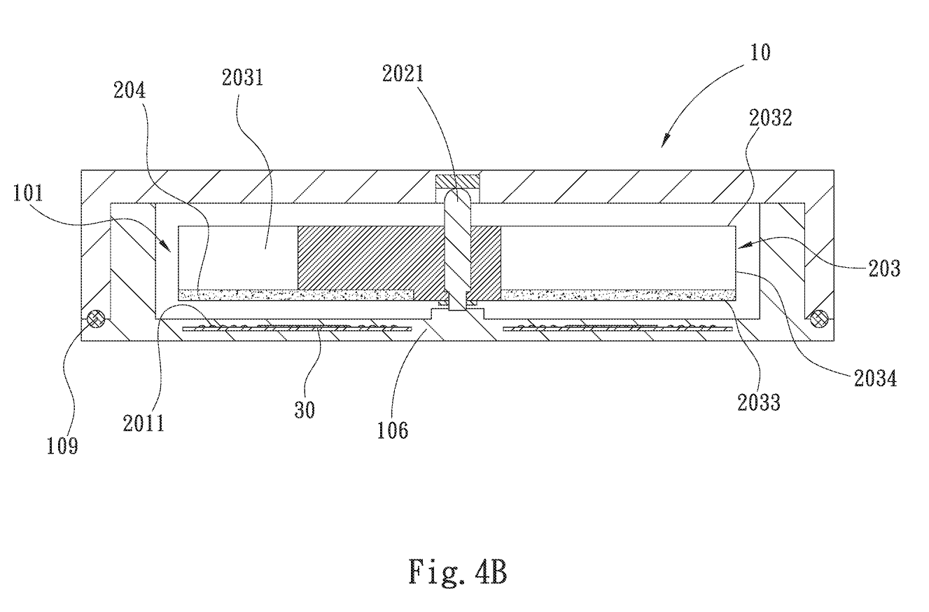

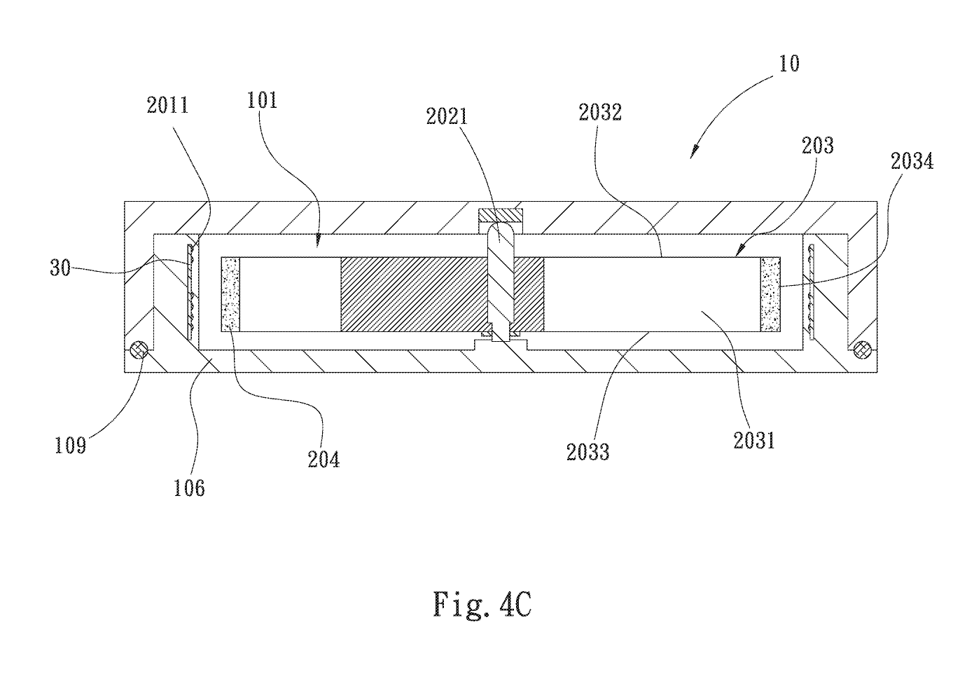

In one embodiment, the above-mentioned circuit board 30 and the coil set 2011 thereon are integrally overmolded inside the liquid storing shell body 10. The circuit board 30 and the stator 201 are disposed outside the liquid chamber 101. The liquid storing shell body 10 isolates the cooling liquid from the stator 201 and the circuit board 30. As shown in FIG. 4A, the circuit board 30 and the coil set 2011 are integrally overmolded inside a top portion (close to the internal wall surface) of the liquid storing shell body 10. The magnetic pole region 204 on the upper edge 2032 of each of the blades 2031 is inductively excited by the opposite coil set 2011 wrapped inside the top portion of the liquid chamber 101. In an embodiment shown in FIG. 4B, the circuit board 30 and the coil set 2011 are integrally overmolded inside a bottom portion of the liquid storing shell body 10. The magnetic pole region 204 on the lower edge 2033 of each of the blades 2031 is inductively excited by the opposite coil set 2011 wrapped inside the bottom portion of the liquid chamber 101. In an embodiment as shown in FIG. 4C, the circuit board 30 and the coil set 2011 are integrally overmolded inside a side portion of the liquid storing shell body 10. The magnetic pole region 204 on the front edge 2034 of each of the blades 2031 is inductively excited by the opposite coil set 2011 wrapped inside the side portion of the liquid chamber 101. Thus, by means of the integral overmold structure of the circuit board 30 and the coil set 2011 inside the liquid storing shell body 10, the waterproof and protection of stator 201 and the circuit board 30 can be achieved. Also, the thickness gap between the stator 201 and the corresponding rotor 202 can be effectively reduced (or shortened) to achieve the thinning effect.

A large magnetic component such as a magnet on the traditional rotor 202 can be replaced by means of the structural design of the present invention using a position (i.e., the upper edge 2032, the lower edge 2033, or the front edge 2034) on each of the blades 2031 to be magnetized to form the magnetic pole region 204 corresponding to the coil set 2011 on the circuit board 30. As a result, the space to receive the traditional magnetic component can be omitted to decrease the entire volume of the liquid storing shell body 10 and to achieve the thinning effect.

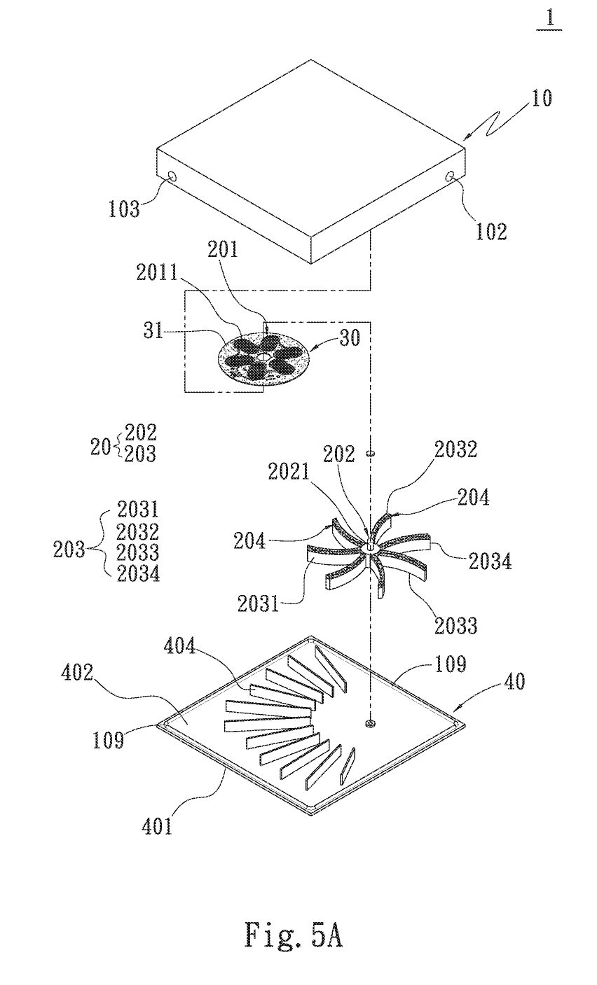

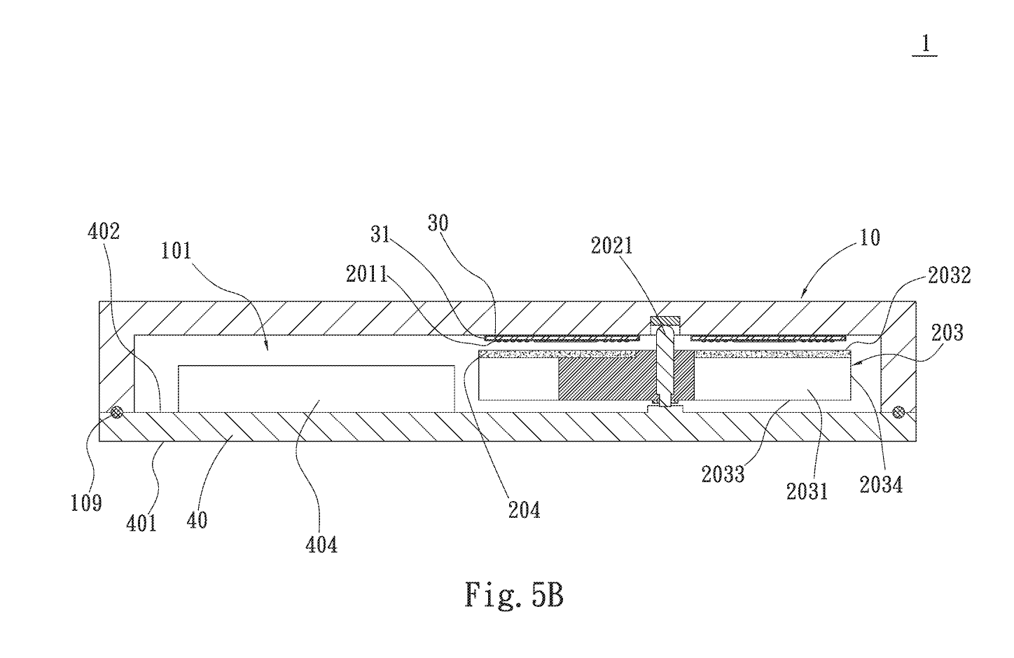

Please refer to FIGS. 5A and 5B, which show the perspective exploded view and the cross-sectional view of the water cooling device according to the second embodiment of the present invention, respectively. The structure, the connecting relation, and the effect of the current embodiment are roughly similar to those of the first embodiment and will not be repeated here. It is mainly the bottom cover 106 of the liquid storing shell body 10 of the first embodiment that is replaced with a heat exchange component 40 connected to the liquid storing shell body 10 to form the current embodiment. That is, the water cooling device 1 further comprises the above-mentioned heat exchange component 40. One side surface of the heat exchange component 40 is connected to the bottom side of the liquid storing shell body 10 to seal the liquid chamber 101. The sealing strength between the liquid storing shell body 10 and the heat exchange component 40 is increased using the washer 109 which is disposed between the liquid storing shell body 10 and the heat exchange component 40 to prevent the cooling liquid from seeping out of the liquid chamber 101. Besides, the heat exchange component 40 is made of metal having high heat conductivity such as aluminum, copper, gold, or silver and has a heat contact surface 401 and a heat exchange surface 402. The heat contact surface 401 is firmly attached to an opposite heat generating device 7 (e.g., a central processing unit or a graphic processing unit) and is used to transfer the heat received from the heat generating device 7 to the heat exchange surface 402 which is disposed in the liquid chamber 101 in which the heat exchange surface 402 contacts the cooling liquid in the liquid chamber 101.

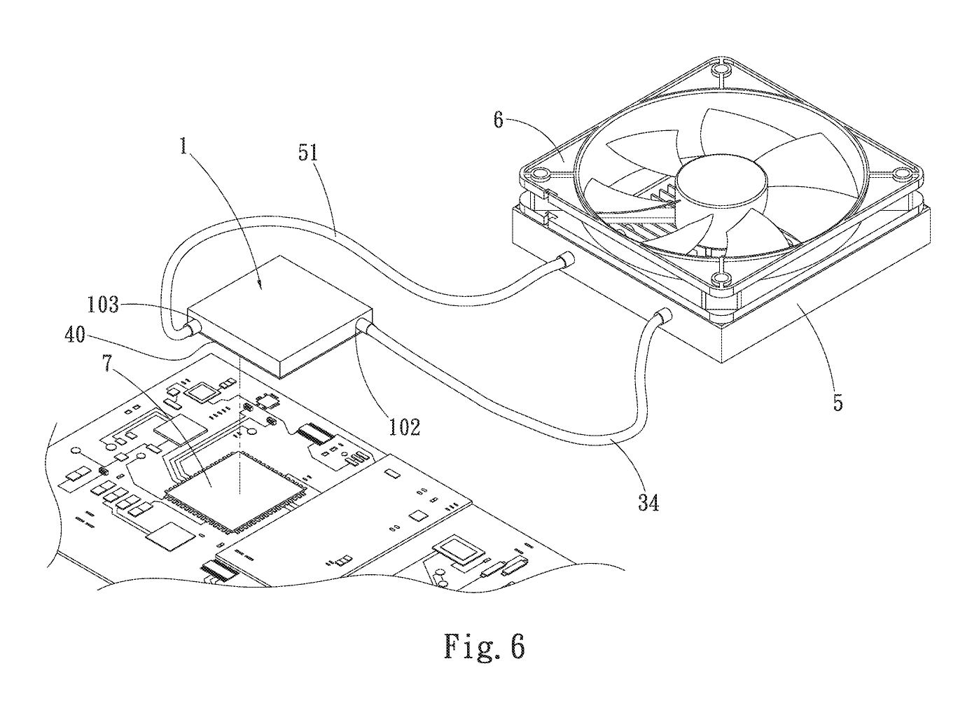

Moreover, the above-mentioned heat exchange component 40 has a plurality of cooling fins 404. The cooling fins 404 are radially spaced on the heat exchange surface 402, but not limited to this. By means of the disposition of the cooling fins 404 on the heat exchange surface 402, the effect of the heat exchange surface 402 can be significantly enhanced. In addition, as shown in FIG. 6, the water cooling device 1 is connected to a heat dissipating device 5 to from a liquid cooling system. The heat dissipating device 5 is connected to and communicates with the inlet 102 and the outlet 103 of the water cooling device 1 through a plurality of flexible tubes 51 such that the propeller 203 in the liquid chamber 101 drives the cooling liquid to circulate and dissipate the heat in the liquid chamber 101 and the heat dissipating device 5. Also, the heat dissipating device 5 can be connected to a fan 6 to facilitate the heat dissipation of the heat dissipating device 5.

When the heat contact surface 401 of the heat exchange component 40 absorbs the heat generated by the heat generating device 7 and transfers it to the heat exchange surface 402, heat transfer is performed between the heat exchange surface 402 and the cooling liquid in the liquid chamber 101 such that the cooling liquid takes away the heat on the heat exchange surface 402 and the cooling fins 404 and flows out of the liquid storing shell body 10 through the outlet 103 and thus the effect of heat dissipation is achieved. As a result, by means of the design of the water cooling device 1 of the present invention, the thinning effect and the volume reduction of the entire liquid storing shell body 10 can be achieved and further the waterproof of the stator 201 can be achieved and the thickness gap between the stator 201 and the rotor 202 can be effectively reduced (or shortened).

In the current embodiment, the circuit board 30 and the coil set 2011 both surrounded by the protective film 31 are firmly adhered on the internal top wall of the liquid chamber 101. The magnetic pole region 204 on the front edge 2034 of each of the blades 2031 is inductively excited by the opposite coil set 2011 on the internal top wall of the liquid chamber 101. In an alternative embodiment, the circuit board 30 and the coil set 2011 both surrounded by the protective film 31 are firmly adhered on the heat exchange surface 402 (i.e., the above-mentioned internal bottom wall of the liquid chamber 101) and the magnetic pole region 204 on the lower edge 2033 of each of the blades 2031 is inductively excited by the coil set 2011 on the opposite internal bottom wall (i.e., the heat exchange surface) of the liquid chamber 101. In an alternative embodiment, the circuit board 30 and the coil set 2011 both surrounded by the protective film 31 are firmly adhered on the internal side wall of the liquid chamber 101 and the magnetic pole region 204 on the front edge 2034 of each of the blades 2031 is inductively excited by the coil set 2011 on the opposite internal side wall of the liquid chamber 101.

In an embodiment, the circuit board 30 and the coil set 2011 are integrally overmolded inside the top portion of the liquid storing shell body 10 and the magnetic pole region 204 on the upper edge 2032 of each of the blades 2031 is inductively excited by the corresponding coil set 2011 wrapped inside the top portion of the liquid chamber 101. In an embodiment, the circuit board 30 and the coil set 2011 are integrally overmolded inside the side portion of the liquid storing shell body 10. The magnetic pole region 204 on the front edge 2034 of each of the blades 2031 is inductively excited by the corresponding coil set 2011 wrapped inside the side portion of the liquid chamber 101.

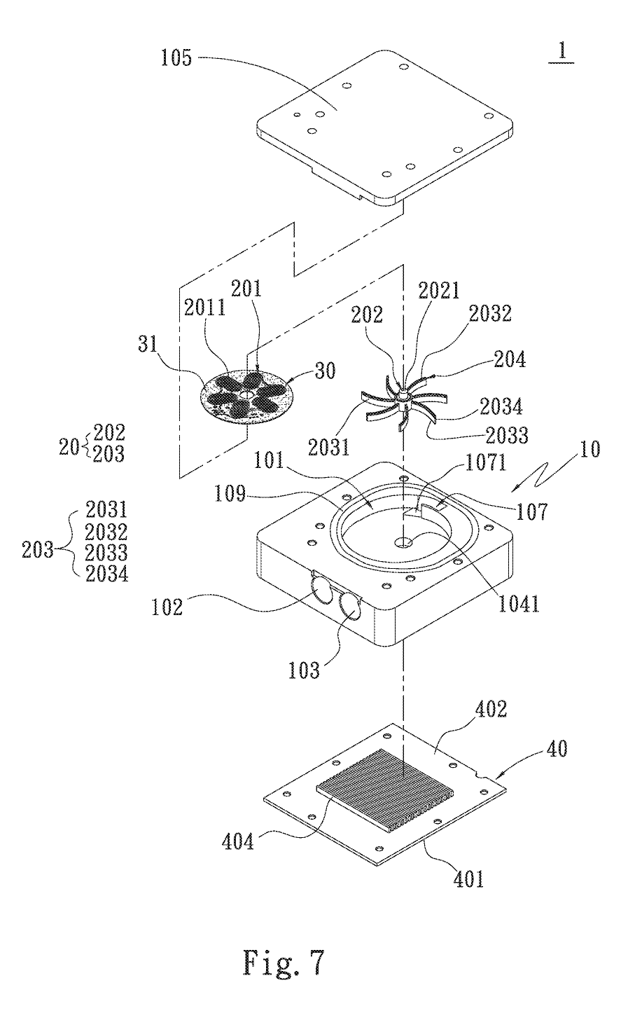

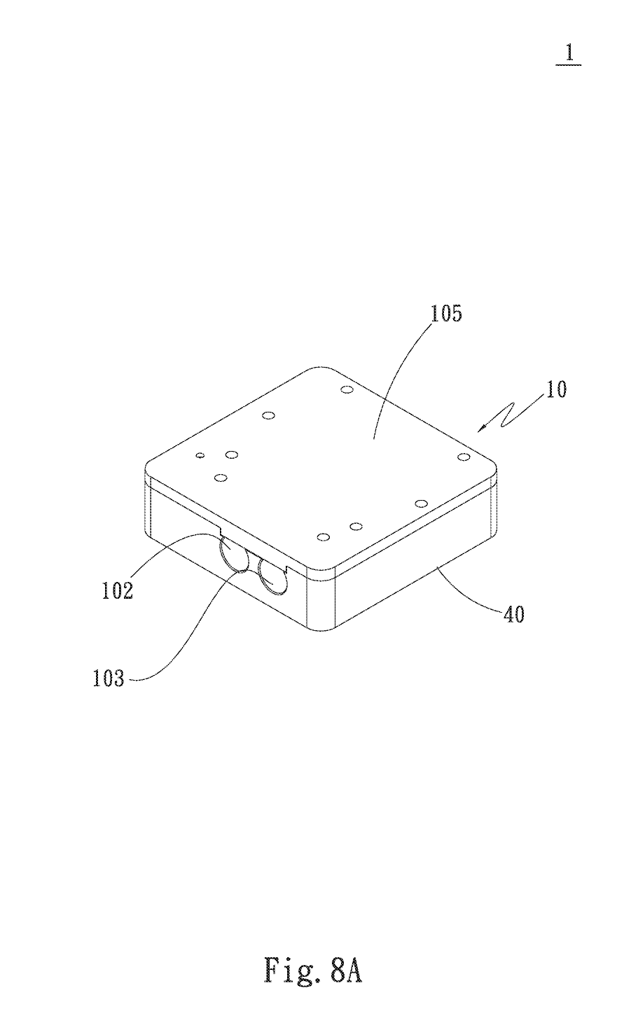

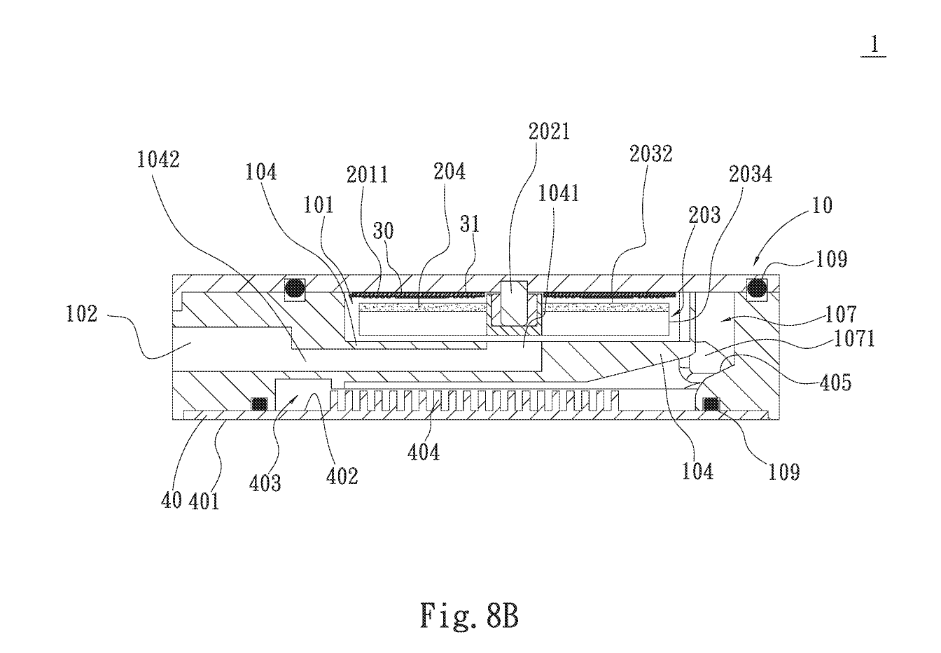

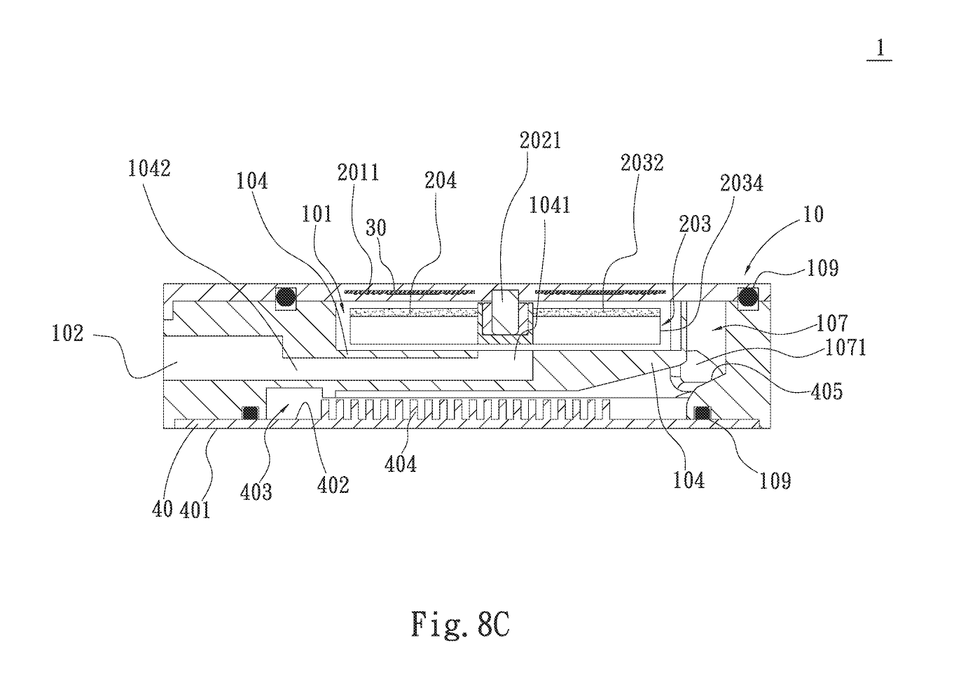

Please refer to FIGS. 7 and 8A, which show the perspective exploded view and the perspective assembled view of the water cooling device according to the third embodiment of the present invention, respectively and also refer to FIG. 8B. The structure, the connecting relation, and the effect of the current embodiment are roughly similar to those of the first embodiment and will not be repeated here. The water cooling device 1 in the second embodiment is redesigned to have an upper chamber and a lower chamber (i.e., a liquid chamber 101 and a heat exchange chamber 403); the inlet 102 and the outlet 103 of the liquid storing shell body 10 are redesigned on the top cover 105 to form the current embodiment. That is, the above-mentioned liquid storing shell body 10 has a top cover 105, a separation part 104, at least one throughhole 1041, and a water channel 107. The top end of the liquid storing shell body 10 is connected to one end surface of the top cover 105 to seal the liquid chamber 101. Another washer 109 is disposed between the liquid storing shell body 10 and the top cover 105 to increase the sealing strength between the liquid storing shell body 10 and the top cover 105 to prevent the cooling liquid from seeping out of the liquid chamber 101.

The separation part 104 is formed at the middle of the liquid storing shell body 10. The separation part 104, the liquid storing shell body 10, and the heat exchange component 40 together define a heat exchange chamber 403. The above-mentioned liquid chamber 101 is disposed above the heat exchange chamber 403. The liquid chamber 101 is above the separation part 104 and the heat exchange chamber 403 is under the separation part 104. The above-mentioned throughhole 1041 is expressed as a throughhole 1041 in the current embodiment and is formed at the middle of the separation part 104 and communicates with the inlet 102 of the liquid storing shell body 10 and the liquid chamber 101. The above-mentioned separation part 104 has a guiding channel 1042 formed therein and disposed between the liquid chamber 101 and the heat exchange chamber 403. The guiding channel 1042 communicates with the inlet 102 of the liquid storing shell body 10 and the liquid chamber 101 to guide the cooling liquid entering from the inlet 102 to enter the liquid chamber 101 above through the throughhole 1041 in which the separation part 104 and the top cover 105 are part of the liquid storing shell body 10.

The above-mentioned water channel 107 disposed between the liquid chamber 101 and an internal side wall of the liquid chamber 101 penetrates through the separation part 104 to communicate with the heat exchange chamber 403, as shown in FIG. 7. The water channel 107 runs between the liquid chamber 101 and the internal side wall opposite to the liquid chamber 101 to form an arc-like shape and is used to guide the cooling liquid driven by the propeller 203 in the liquid chamber 101 to the heat exchange chamber 403. Then, the cooling liquid in the heat exchange chamber 403 flows out via the corresponding outlet 103. The water channel 107 has a first inclined surface 1071 extending from the bottom of the water channel 107 in the liquid chamber 101 to penetrate through the separation part 104 and slope downward. A second inclined surface 405 is disposed on an internal wall of the heat exchange chamber 403 opposite to the water channel 107. The second inclined surface 405 is adjacent to, connected to, and opposite to the first inclined surface 1071. The elevation of the first inclined surface 1071 is higher than that of the second inclined surface 405 such that a step difference is formed between the first and the second inclined surfaces 1071, 405. In the current embodiment, the first inclined surface 1071 is roughly perpendicular to the second inclined surface 405, but not limited to this.

Therefore, the usage of the first and second inclined surfaces 1071, 405 can reduce the flow speed of the cooling liquid in the water channel 107 which is then guided to the heat exchange chamber 403. That is, the reduction of the flow speed can be achieved through the first and second inclined surfaces 1071, 405. Besides, the flow of the cooling liquid is made smooth and further eddies (or turbulence) can be prevented when the cooling liquid just flows into the heat exchange chamber 403 and the bubbles caused by the impact of the cooling liquid just entering the heat exchange chamber 403 can be decreased.

In the current embodiment, the circuit board 30 and the coil set 2011 both surrounded by the protective film 31 are firmly adhered on the internal side of the top cover 105 of the liquid storing shell body 10 (i.e., the internal top wall of the liquid chamber 101). The magnetic pole region 204 on the front edge 2034 of each of the blades 2031 is inductively excited by the opposite coil set 2011 on the internal top wall of the liquid chamber 101 (i.e., the internal side of the top cover 105 of the liquid storing shell body 10). In an alternative embodiment, the circuit board 30 and the coil set 2011 both surrounded by the protective film 31 are firmly adhered on a side of the separation part 104 opposite to the top cover 105 (i.e., the internal bottom wall of the liquid chamber 101) and the magnetic pole region 204 on the lower edge 2033 of each of the blades 2031 is inductively excited by the coil set 2011 on the opposite internal bottom wall of the liquid chamber 101. In an alternative embodiment, the circuit board 30 and the coil set 2011 both surrounded by the protective film 31 are firmly adhered on the internal side wall of the liquid chamber 101 and the magnetic pole region 204 on the front edge 2034 of each of the blades 2031 is inductively excited by the coil set 2011 on the opposite internal side wall of the liquid chamber 101.

In an embodiment as shown in FIG. 8C, the circuit board 30 and the coil set 2011 are integrally overmolded inside the top portion of the liquid storing shell body 10 (i.e., inside the top cover 105 of the liquid storing shell body 10) and the magnetic pole region 204 on the upper edge 2032 of each of the blades 2031 is inductively excited by the opposite coil set 2011 wrapped inside the top cover 105 of the liquid storing shell body 10. In an embodiment, the circuit board 30 and the coil set 2011 are integrally overmolded inside the separation part 104 of the liquid storing shell body 10 and the magnetic pole region 204 on the lower edge 2033 of each of the blades 2031 is inductively excited by the corresponding coil set 2011 wrapped inside the separation part 104 of the liquid storing shell body 10.

Therefore, by means of the design of the water cooling device 1 of the present invention, the thinning effect and the volume reduction of the entire liquid storing shell body 10 can be achieved and further the waterproof of the stator 201 can be achieved and the thickness gap between the stator 201 and the rotor 202 can be effectively reduced (or shortened).

The above-mentioned embodiments are only the preferred ones of the present invention. All variations regarding the above method, shape, structure, and device according to the claimed scope of the present invention should be embraced by the scope of the appended claims of the present invention.

What is claimed is:

1. A water cooling device, comprising:
a liquid storing shell body having a liquid chamber, an inlet, and an outlet, wherein the liquid chamber communicates with the inlet and the outlet to allow a cooling liquid to flow through the interior thereof; and
a pump used to circulate the cooling liquid and comprising a stator and a rotor, wherein the stator has a coil set disposed electrically on a circuit board, wherein the circuit board and the coil set thereon are both disposed on at least one inner wall of the liquid chamber or integrally overmolded in the liquid storing shell body, wherein the circuit board and the coil set are both isolated from the cooling liquid, wherein the rotor and a propeller oppositely connected to the rotor are received in the liquid chamber and exposed in the cooling liquid, wherein the propeller is provided with a plurality of blades made of metal, wherein at least one magnetic pole region is magnetized on each of the blades opposite to the coil set, wherein the magnetic pole region of the each of the blades is inductively excited by the coil set.

2. The water cooling device according to claim 1, wherein an upper edge or a lower edge of the each of the blades is axially magnetized to form the magnetic pole region, wherein a protective film surrounding the circuit board and the coil set is disposed on an internal top wall or an internal bottom wall of the liquid chamber and corresponds to the magnetic pole regions of the blades.

3. The water cooling device according to claim 1, wherein a front edge of the each of the blades is radially magnetized to form the magnetic pole region, wherein a protective film surrounding the circuit board and the coil set is disposed on an internal side wall of the liquid chamber and corresponds to the magnetic pole regions of the blades.

4. The water cooling device according to claim 1, wherein an upper edge or a lower edge of the each of the blades is axially magnetized to form the magnetic pole region, wherein the circuit board and the coil set are integrally overmolded inside a top portion or a bottom portion of the liquid storing shell body and correspond to the magnetic pole regions of the blades, wherein the circuit board and the stator are disposed outside the liquid chamber, wherein the liquid storing shell body isolates the cooling liquid from the stator and the circuit board.

5. The water cooling device according to claim 1, wherein a front edge of the each of the blades is radially magnetized to form the magnetic pole region, wherein the circuit board and the coil set are integrally overmolded inside a side portion of the liquid storing shell body and correspond to the magnetic pole regions on the front edges of the blades, wherein the circuit board and the stator are disposed outside the liquid chamber, wherein the liquid storing shell body isolates the cooling liquid from the stator and the circuit board.

6. The water cooling device according to claim 1, wherein the rotor has a shaft, wherein one end of the shaft is connected to the propeller and the other end of the shaft is axially disposed on an internal wall of the liquid chamber, wherein the inlet and the outlet are individually disposed on two sides of the liquid storing shell body.

7. The water cooling device according to claim 1, further comprising a heat exchange component oppositely connected to the liquid storing shell body, wherein the heat exchange component has a heat contact surface and a heat exchange surface which contacts the cooling liquid in the liquid chamber.

8. The water cooling device according to claim 1, further comprising a heat exchange component oppositely connected to the liquid storing shell body, wherein the liquid storing shell body further comprises a separation part, at least one throughhole, and a water channel, wherein the separation part is formed at the middle of the liquid storing shell body, wherein the separation part, the liquid storing shell body, and the heat exchange component together define the liquid chamber and a heat exchange chamber communicating with the outlet, wherein the throughhole is formed on the separation part and communicates with the inlet and the liquid chamber disposed above the heat exchange chamber, wherein the water channel is disposed between the liquid chamber and an internal side wall of the liquid chamber and penetrates through the separation part to communicate with the heat exchange chamber.

9. The water cooling device according to claim 8, wherein the heat exchange component has a heat contact surface and a heat exchange surface which contacts the cooling liquid in the liquid chamber.

10. The water cooling device according to claim 8, wherein the water channel has a first inclined surface extending from the bottom of the water channel in the liquid chamber to penetrate through the separation part and slope downward, wherein a second inclined surface is disposed on an internal wall of the heat exchange chamber opposite to the water channel, wherein the second inclined surface is adjacent to, connected to, and opposite to the first inclined surface.

11. The water cooling device according to claim 10, wherein the elevation of the first inclined surface is higher than that of the second inclined surface such that a step difference is formed between the first and the second inclined surfaces both of which are roughly perpendicular to each other.

12. The water cooling device according to claim 8, wherein an upper edge or a lower edge of the each of the blades is axially magnetized to form the magnetic pole region, wherein a protective film surrounding the circuit board and the coil set is disposed on an internal top wall or an internal bottom wall of the liquid chamber and corresponds to the magnetic pole regions of the blades.

13. The water cooling device according to claim 8, wherein an upper edge or a lower edge of the each of the blades is axially magnetized to form the magnetic pole region, wherein the circuit board and the coil set are integrally overmolded inside a top portion of the liquid storing shell body or inside the separation part and correspond to the magnetic pole regions of the blades, wherein the circuit board and the stator are disposed outside the liquid chamber, wherein the liquid storing shell body isolates the cooling liquid from the stator and the circuit board.

14. The water cooling device according to claim 1, wherein the coil set is formed on the circuit board by printing, stacking, etching, or layout.
